(19) United States
(12) Patent Application Publication
(10) Pub. No.: US 2026/0249398 A1
(43) Pub. Date: Aug. 27, 2026

(54) METHOD FOR FORMING A STACKED WAFER

(71) Applicant: DISCO CORPORATION, Tokyo (JP)

(72) Inventor: Hiroshi Morikazu, Tokyo (JP)

(21) Appl. No.: 19/360,616

(22) Filed: Oct. 16, 2025

(30) Foreign Application Priority Data
Oct. 31, 2024 (JP) 2024-191265

(51) Int. Cl. B23K 26/53; B23K 101/40; H01L 21/304; H01L 21/67

(52) U.S. Cl. CPC B23K 26/53; H10P 52/00; H10P 72/0428; B23K 2101/40

(57) ABSTRACT

A method for forming a stacked wafer by transferring a first device layer of a first wafer, in which the first device layer is formed on a surface of a substrate via an insulating film, onto a second wafer, in which a second device layer is formed, includes a bonding step including bonding a side of the first wafer having the first device layer and a side of the second wafer having the second device layer together; a processed layer forming step including irradiating the substrate of the first wafer from a substrate side of the first wafer with a laser beam having a transmissive wavelength in pulses to form a processed layer in the insulating film; and a separation step including separating the substrate and the first device layer by the processed layer.

### CROSS REFERENCE TO RELATED APPLICATION

This application is based upon and claims the benefit of priority from the prior Japanese Patent Application No. 2024-191265 filed on Oct. 31, 2024; the entire contents of which are incorporated herein by reference.

### FIELD

The present disclosure relates to a method for forming a stacked wafer in which wafers having devices formed thereon are stacked.

### BACKGROUND

Japanese Patent Application Laid-Open Publications No. 2023-126270 and No. 2013-021225 disclose a method for forming a stacked wafer, in which two wafers, each having a device layer formed on a surface thereof, are bonded with their device layers facing each other. According to this method, a laser beam is emitted from a substrate side of one of the wafers, and a portion between the device layer and the substrate is planarly processed with the laser to separate the substrate, thereby transferring the device layer of the one of the wafers onto the other of the wafers. In the one of the wafers, in the portion between the substrate and the device layer, in order to prevent damages in the device layer that may be caused by the emitted laser light transmitting therethrough, a laser absorbable layer having a predetermined thickness is formed.

### SUMMARY

In the above-described method for forming a stacked wafer, since an interface between the substrate and the laser absorbable layer is irradiated with the laser berm, a problem may be caused such that the substrate of the one of the wafers is likely to be damaged by the laser beam.

The present disclosure has been made in view of the foregoing, and one of its objects is to provide a method for forming a stacked wafer, in which damage to a substrate of a wafer having an insulating film that is irradiated with a laser beam during formation of a processed layer may be suppressed.

According to an aspect of the present disclosure, a method for forming a stacked wafer by transferring a first device layer of a first wafer, in which the first device layer is formed on a surface of a substrate via an insulating film, onto a second wafer, in which a second device layer is formed, includes a bonding step including bonding a side of the first wafer having the first device layer and a side of the second wafer having the second device layer together; a processed layer forming step including irradiating the substrate of the first wafer from a substrate side of the first wafer with a laser beam having a transmissive wavelength in pulses to form a processed layer in the insulating film; and a separation step including separating the substrate and the first device layer by the processed layer.

According to the present disclosure, as the processed layer is formed in the insulating film by the laser beam emitted from the substrate side of the first wafer in the processed layer forming step, damage to the substrate of the first wafer by the laser beam may be suppressed.

### BRIEF DESCRIPTION OF THE DRAWINGS

FIG. 1A illustrates a preparation step, FIG. 1B illustrates a bonding step, FIG. 1C illustrates a processed layer forming step, and FIG. 1D illustrates a separation step, in a method for forming a stacked wafer according to an embodiment.

FIG. 2A illustrates a polishing step, FIG. 2B illustrates the preparation step for a second time, and FIG. 2C illustrates the bonding step for the second time.

### DESCRIPTION OF EMBODIMENTS

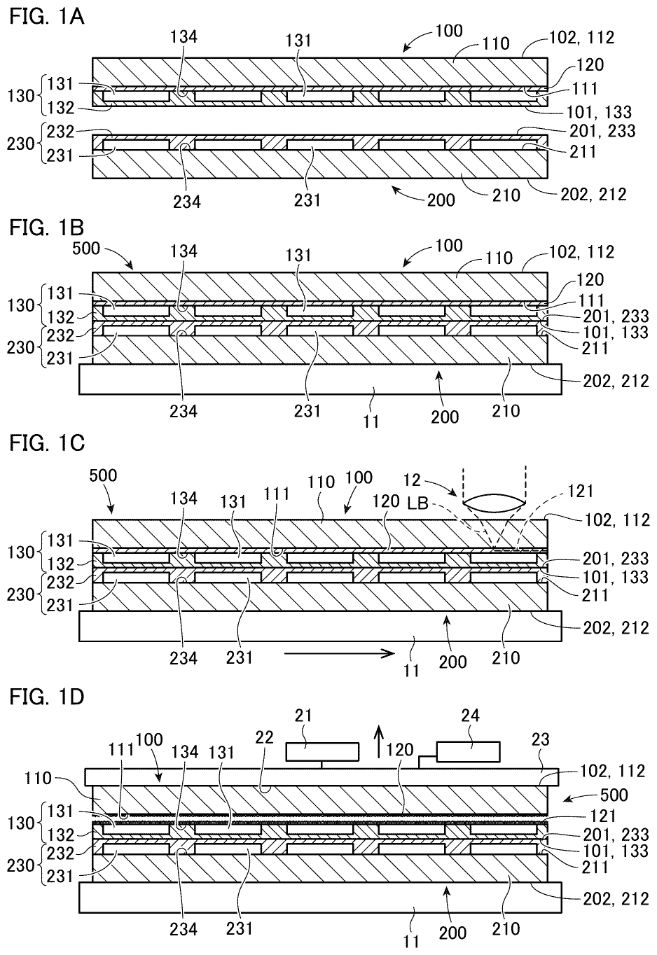

Hereinafter, with reference to the accompanying drawings, a method for forming a stacked wafer according to an illustrative embodiment will be described. FIG. 1A illustrates a preparation step, FIG. 1B illustrates a bonding step, FIG. 1C illustrates a processed layer forming step, and FIG. 1D illustrates a separation step. It should be noted that the steps shown in the drawings of the illustrative embodiment are merely examples and are not limited to this configuration.

### Preparation Step

The preparation step is a preparation for forming a stacked wafer 500 (see FIG. 1B), where a first wafer 100 and a second wafer 200, as shown in FIG. 1A, each having a disk shape are prepared. The first wafer 100 includes a front surface 101 and a back surface 102, which are planes orthogonal to a thickness direction. The first wafer 100 is disposed in an orientation such that the front surface 101 faces downward in FIG. 1A and the back surface 102 faces upward in FIG. 1A. The second wafer 200 includes a front surface 201 and a back surface 202, which are planes orthogonal to the thickness direction. The second wafer 200 is disposed in an orientation such that the front surface 201 faces upward in FIG. 1A and the back surface 202 faces downward in FIG. 1A.

The first wafer 100 includes a first substrate 110 (substrate) made of silicon, and a first device layer 130 formed on a front surface 111, which is a surface on one side in a thickness direction of the first substrate 110, via an insulating film 120. The back surface 102 of the first wafer 100 is formed of a back surface 112 of the first substrate 110.

The insulating film 120 is an interlayer insulating film laminated between the first substrate 110 and the first device layer 130. The insulating film 120 may be any of a silicon oxide film (SiO2 film), a silicon carbide film (SiC film), a silicon nitride film (SiN film), or a silicon carbonitride film (SiCN film). The insulating film 120 absorbs a laser beam LB (see FIG. 1C) emitted thereat in the processed layer forming step.

The first device layer 130 includes a plurality of first devices 131 and a first surface film 132 which is formed as an insulating film. The front surface 101 of the first wafer 100 is formed of a front surface 133 of the first surface film 132 in the first device layer 130.

Each of the plurality of first devices 131 includes an element for composing, for example, an IC, a semiconductor memory, or an image sensor. The plurality of first devices 131 are formed in a plurality of regions partitioned by a plurality of streets 134 formed in a grid pattern.

The first surface film 132 may be, similar to the insulating film 120, any of a silicon oxide film (SiO2 film), a silicon carbide film (SiC film), a silicon nitride film (SiN film), or a silicon carbonitride film (SiCN film).

The second wafer 200 includes a second substrate 210 (substrate) made of silicon similarly to the above-described first substrate 110, and a second device layer 230 formed on a front surface 211, which is a surface on one side in a thickness direction of the second substrate 210. The back surface 202 of the second wafer 200 is formed of a back surface 212 of the second substrate 210.

The second device layer 230 is formed similarly to the first device layer 130, and includes a plurality of second devices 231 and a second surface film 232 which is formed as an insulating film. The front surface 201 of the second wafer 200 is formed of a front surface 233 of the second surface film 232 in the second device layer 230.

Each of the plurality of second devices 231 includes an element similar to that in the first device 131, and is formed in a plurality of regions partitioned by a plurality of streets 234 formed in a grid pattern corresponding to the first devices 131. The second surface film 232 is made of a material similar to that of the insulating film 120 and the first surface film 132.

In the preparation step, as preparation for the bonding step using plasma-activated bonding, preparation for enabling the front surface 201 of the second wafer 200 (the front surface 233 of the second surface film 232) to be bonded to the front surface 101 of the first wafer 100 (the front surface 133 of the first surface film 132) is performed.

In the preparation step, for example, plasma of a rare gas generated by using a rare gas and high-frequency power is emitted at each of the front surface 133 of the first surface film 132 of the first wafer 100 and the front surface 233 of the second surface film 232 of the second wafer 200. As a result, the front surfaces 133, 233 of the first surface film 132 and the second surface film 232 are activated so that the first surface film 132 and the second surface film 232 are enabled to function as bonding members in the bonding step.

### Bonding Step

After the preparation step is completed, as shown in FIG. 1B, the bonding step is performed with plasma-activated bonding. In the bonding step, the second wafer 200 is located to be held on a chuck table 11 with the back surface 202 facing downward. Further, the first wafer 100 is placed to face the second wafer 200 such that the front surface 101, which forms the surface of the first wafer 100 on the first device layer 130 side, faces the front surface 201, which forms the surface of the second wafer 200 on the second device layer 230 side. Furthermore, after the devices 131, 231 on the first wafer 100 and the second wafer 200 are aligned with one another in a horizontal direction, the front surface 101 of the first wafer 100 is pressed against the front surface 201 of the second wafer 200.

Accordingly, the first surface film 132 of the first wafer 100 and the second surface film 232 of the second wafer 200 both functioning as a bonding member are bonded, thereby forming a stacked wafer 500. In the stacked wafer 500 formed in the bonding step, the first device layer 130 side of the first wafer 100 and the second device layer 230 side of the second wafer 200 are bonded together.

### Processed Layer Forming Step

After the bonding step is completed, the processed layer forming step as shown in FIG. 1C is performed. In the processed layer forming step, the laser beam LB having a transmissive wavelength is emitted in pulses from a laser emitting unit 12 to irradiate the first substrate 110 of the first wafer 100 from the first substrate 110 side (the back surface 102 side). The emitted laser beam LB is focused into the insulating film 120 by an unshown condensing lens and absorbed by the insulating film 120, whereby a part of the insulating film 120 is sublimated and ablated, and a processed layer 121 is formed in the insulating film 120. In this instance, the chuck table 11 holding the stacked wafer 500 is relatively moved in a zigzag manner with respect to the laser emitting unit 12 along the horizontal direction, thereby irradiating the entire insulating film 120 with the laser beam LB.

For the laser beam LB for forming the processed layer 121, an optical penetration length d into the insulating film 120 with respect to a wavelength λ and an extinction coefficient k is obtained by the following Expression (1).

Optical penetration length d=λ/(4πk) Expression (1)

This optical penetration length d is defined as a distance from an interface between the first substrate 110 and the insulating film 120, into which the laser beam LB enters, to a position where the laser beam LB is focused. The wavelength λ and the extinction coefficient k of the laser beam LB emitted from the laser emitting unit 12 are adjusted such that the optical penetration length d is equal to or less than the film thickness of the insulating film 120. As such, the first wafer 100 and the second wafer 200 are prepared so that the emitted laser beam LB may be focused inside the insulating film 120.

The laser beam LB used in the laser processing step is set to have the wavelength λ within a range from 2700 nm to 2900 nm, inclusive, and more preferably, set to have the wavelength λ of 2800 nm. By setting the wavelength λ to such a value, the laser beam LB is enabled to transmit the first substrate 110 of the first wafer 100 while the insulating film 120 absorbs the energy of the laser beam LB efficiently.

The wavelength λ of the laser beam LB is preferably equal to or less than the thickness of the insulating film 120. Preferably, when the wavelength λ of the laser beam LB is set within the above range, the insulating film 120 may be formed to have a thickness within a range from 0.1 μm to 2.5 μm, inclusive. By setting the wavelength λ of the laser beam LB and the thickness of the insulating film 120 as above, the processed layer 121 may be formed in the insulating film 120 while reducing the thickness of the insulating film 120, thereby shortening the processing time required for forming the insulating film 120.

### Separation Step

After the processed layer forming step is completed, the separation step as shown in FIG. 1D is performed. In the separation step, the back surface 102 of the first wafer 100 is held on a suction pad 23, which is connected to a suction source 21 and generates a negative pressure at a holding surface 22. Further, the suction pad 23 is lifted via a lift/lower mechanism 24 to apply a force for separating the first wafer 100 from the second wafer 200. Accordingly, in the stacked wafer 500, the first substrate 110 and the first device layer 130 of the first wafer 100 are separated by the processed layer 121, and the first device layer 130 of the first wafer 100 is transferred onto the second wafer 200.

According to the above embodiment, in the processed layer forming step, the processed layer 121 is formed by the laser beam LB emitted from the first substrate 110 side of the first wafer 100 so as to be enclosed inside the insulating film 120. Thus, damage to the first substrate 110 of the first wafer 100 by irradiation with the laser beam LB may be suppressed. Further, the processed layer 121 may be formed while avoiding damage to the first and second devices 131, 231 of the first and second wafers 100, 200 due to the irradiation with the laser beam LB. In particular, by using a SiCN film as the insulating film 120, diffusion of the laser beam LB into the first and second devices 131, 231 may be prevented more effectively, thereby avoiding damage to the first and second devices 131, 231.

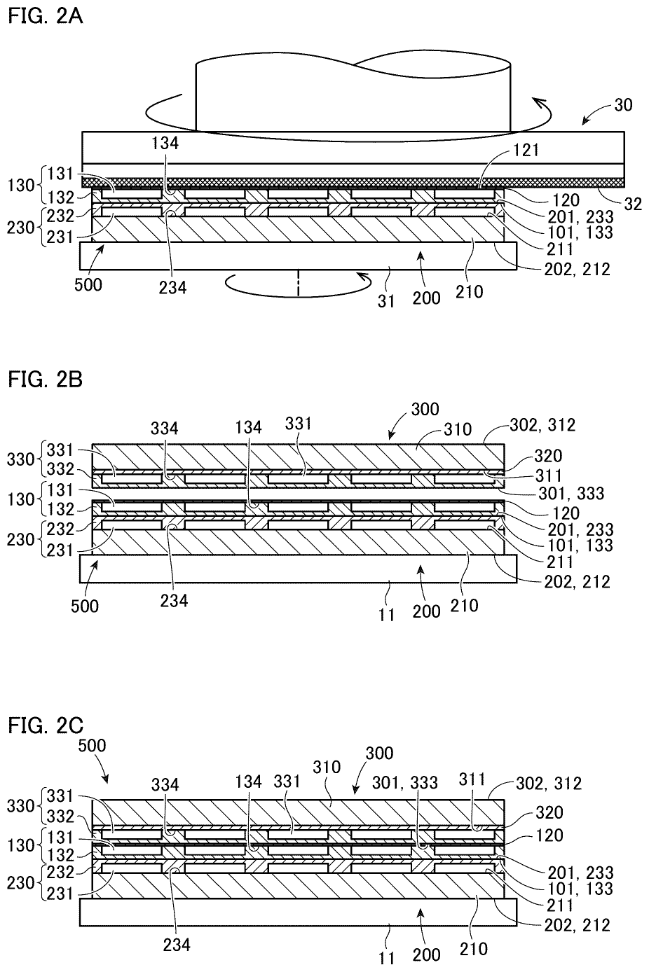

After the separation step in the stacking method of the embodiment is performed as above, optionally, another wafer may be further stacked onto the stacked wafer 500. With reference to FIGS. 2A-2C, a case where a third wafer 300 is further stacked will be described herein. FIG. 2A illustrates a polishing step, FIG. 2B illustrates the preparation step for the third wafer, and FIG. 2C illustrates the bonding step for a second time. In the following description, the third wafer 300 is configured similarly to the first wafer 100, and for the components in the third wafer 300 corresponding to those in the first wafer 100, the term “first” is replaced with “third,” and the hundreds digit of each reference numeral is changed from “1” to “3,” and detailed description those is omitted.

### Polishing Step

In the polishing step performed after the separation step, as shown in FIG. 2A, a polishing mechanism 30 is used. In the polishing step, after the back surface 202 of the second wafer 200 in the stacked wafer 500 is held facing downward on a chuck table 31 of the polishing mechanism 30, a polishing pad 32 in the polishing mechanism 30 faces the processed layer 121 exposed in the separation step. Further, while rotating the chuck table 31 and the polishing pad 32 about vertical axes, a lower surface of the polishing pad 32 is pressed against the exposed processed layer 121 in the insulating film 120 of the stacked wafer 500, thereby polishing the insulating film 120. By polishing as above, unevenness on an upper surface (a surface on one side in the thickness direction) of the stacked wafer 500 formed of the insulating film 120 is removed. In the polishing step, wet polishing or CMP is performed as long as unevenness in the insulating film 120 is removable thereby. Optionally, dry polishing may also be performed.

### Preparation Step for Second Time

After the polishing step is completed, the preparation step for the second time is performed. In the preparation step, preparation for enabling a front surface 301 of the third wafer 300 (a front surface 333 of the third surface film 332, see FIG. 2B) to be bonded to the insulating film 120 polished in the stacked wafer 500 by plasma-activated bonding is performed. For example, plasma of a rare gas generated by using a rare gas and high-frequency power may be emitted at each of the insulating film 120 of the stacked wafer 500 and the front surface 333 of the third surface film 332 of the third wafer 300. As a result, the insulating film 120 of the stacked wafer 500 and the front surface 333 of the third surface film 332 are activated so that the insulating film 120 and the third surface film 332 may function as bonding members in the bonding step.

### Bonding Step for Second Time

After the second preparation step is completed, the bonding step for the second time as shown in FIG. 2C is performed with plasma-activated bonding. In this bonding step, the stacked wafer 500 is located to be held on the chuck table 11 with the back surface 202 facing downward. Further, the third wafer 300 is placed to face the stacked wafer 500 such that the front surface 301, which forms the surface of the third wafer 300 on the third device layer 330 side, faces the insulating film 120 of the stacked wafer 500. Furthermore, after the devices 131, 231, 331 on the first, second, and third wafers 100, 200, 300 are aligned with one another in the horizontal direction, the front surface 301 of the third wafer 300 is pressed against the insulating film 120 of the stacked wafer 500.

Accordingly, the insulating film 120 of the stacked wafer 500 and the third surface film 332 of the third wafer 300 both functioning as a bonding member are bonded, thereby forming the stacked wafer 500 in which the first, second, and third wafers 100, 200, 300 are stacked.

Although not shown in the drawings, after the bonding step with the third wafer 300 is performed, a processed layer may be formed in an insulating film 320 of the third wafer 300 by performing a processed layer forming step similarly to the processed layer forming step described above. Thereafter, by performing a separation step similar to the separation step described above, a third substrate 310 of the third wafer 300 is separated from the third device layer 330, thereby enabling the third device layer 330 to be transferred onto the first device layer 130.

Note that embodiment of the present disclosure may not necessarily be limited to the configuration described above but may be modified in various ways. In the embodiment described above, sizes or forms of the components illustrated in the accompanying drawings are not limited thereto but may be modified optionally within the scope of the effects of the present disclosure. Moreover, the embodiment may be modified optionally without departing from the scope of the object of the present disclosure.

For example, in the above illustrative embodiment, cases where two or three wafers are stacked to form the stacked wafer 500 have been described, but a stacked wafer 500 in which four or more wafers are stacked may be formed by repeating the same steps as described above.

For another example, although an example has been illustrated in which the common chuck table 11 is used in steps other than the polishing step, the present disclosure is not limited thereto, but the chuck table 11 may be changed according to devices used for performing different steps.

As described above, the present disclosure has an advantageous effect of suppressing damage to a substrate of a wafer having an insulating film irradiated with a laser beam during formation of a processed layer.

What is claimed is:

1. A method for forming a stacked wafer by transferring a first device layer of a first wafer, in which the first device layer is formed on a surface of a substrate via an insulating film, onto a second wafer in which a second device layer is formed, comprising:
a bonding step including bonding a side of the first wafer having the first device layer and a side of the second wafer having the second device layer together;
a processed layer forming step including irradiating the substrate of the first wafer from a substrate side of the first wafer with a laser beam having a transmissive wavelength in pulses to form a processed layer in the insulating film; and
a separation step including separating the substrate and the first device layer by the processed layer.

2. The method according to claim 1,
wherein an optical penetration length of the laser beam is obtained by an expression: optical penetration length d=λ/(4πk); and
wherein the optical penetration length is less than or equal to a thickness of the insulating film.

3. The method according to claim 1, wherein the wavelength of the laser beam is less than or equal to a thickness of the insulating film.

4. The method according to claim 1, wherein, when the wavelength of the laser beam is within a range from 2700 nm to 2900 nm, inclusive, a thickness of the insulating film is set within a range from 0.1 μm to 2.5 μm, inclusive.
